(19) United States
(12) Patent Application Publication
(10) Pub. No.: US 2026/0247751 A1
(43) Pub. Date: Aug. 20, 2026

(54) Light-Emitting Chip and Method for Manufacturing Same

(71) Applicant: CHONGQING KONKA PHOTOELECTRIC TECHNOLOGY RESEARCH INSTITUTE CO., LTD., Chongqing (CN)

(72) Inventors: Ming-Ta TSAI, Chongqing (CN); Zhongshan FENG, Chongqing (CN); Ching-Chung CHEN, Chongqing (CN)

(73) Assignee: CHONGQING KONKA PHOTOELECTRIC TECHNOLOGY RESEARCH INSTITUTE CO., LTD., Chongqing (CN)

(21) Appl. No.: 19/484,104

(22) PCT Filed: Jul. 22, 2021
(86) PCT No.: PCT/CN2021/107797

§ 371 Date: Nov. 13, 2025

(51) Int. Cl. H10H 20/821; H10H 20/832

(52) U.S. Cl. CPC H10H 20/821; H10H 20/835

(57) ABSTRACT

A light-emitting chip and a method for manufacturing the same are provided. Top surfaces of a first semiconductor layer, a first active layer, a second semiconductor layer and a substrate included in the light-emitting chip are located on a first horizontal plane, and bottom surfaces of the first semiconductor layer, the first active layer, the second semiconductor layer and the substrate included in the light-emitting chip are located on a second horizontal plane; and the top surfaces of the first semiconductor layer, the first active layer, the second semiconductor layer and the substrate serve as light-emitting surfaces.

### TECHNICAL FIELD

The present disclosure relates to the field of light-emitting chips, and in particular to a light-emitting chip and a method for manufacturing the same.

### BACKGROUND

A typical epitaxial layer structure of a current Light-emitting diode (LED) chip generally includes a substrate, an N-type semiconductor layer, an active layer, and a P-type semiconductor layer stacked in sequence from bottom to top. Light generated by the LED chip needs to penetrate through the active layer, the N-type semiconductor layer and the substrate in sequence so as to be emitted from a bottom surface of the substrate. A transmission path of the light is long, and energy attenuation is large, which is not beneficial for improving the light-emitting efficiency, especially for light with high energy which is easily absorbed by semiconductor materials, electrodes and the like and then converted into heat energy, for example, ultraviolet light.

Therefore, how to improve the light-emitting efficiency of the LED chip is a problem urgently needed to be solved at present.

### SUMMARY

In view of the above deficiencies of the related art, embodiments of the present disclosure provide a light-emitting chip and a method for manufacturing the same, which can solve the problem of how to improve the light-emitting efficiency of an LED chip in the related art.

The embodiments of the present disclosure provide a light-emitting chip, including a first semiconductor layer, a first active layer, a second semiconductor layer and a substrate, where
the first semiconductor layer, the first active layer and the second semiconductor layer are located on a first side of the substrate; top surfaces of the first semiconductor layer, the first active layer, the second semiconductor layer and the substrate are located on a first horizontal plane and serve as light-emitting surfaces; and bottom surfaces of the first semiconductor layer, the first active layer, the second semiconductor layer and the substrate are located on a second horizontal plane; and
the light-emitting chip further includes a first electrode electrically connected with the first semiconductor layer and a second electrode electrically connected with the second semiconductor layer, and the first electrode and the second electrode are disposed insulated from each other.

According to the light-emitting chip, the top surfaces of the first semiconductor layer, the first active layer, the second semiconductor layer and the substrate are located on the first horizontal plane, the bottom surfaces of the first semiconductor layer, the first active layer, the second semiconductor layer and the substrate are located on the second horizontal plane, namely, the first semiconductor layer, the first active layer, the second semiconductor layer and the substrate are disposed in a coplanar manner. Moreover, the top surfaces of the first semiconductor layer, the first active layer, the second semiconductor layer and the substrate directly serve as the light-emitting surfaces, part of the generated light can be directly emitted out through the first semiconductor layer, the first active layer and the second semiconductor layer, so that an emission path of the part of light is shortened, absorption of light energy can be reduced to the maximum extent, and therefore, the light-emitting efficiency of the light-emitting chip can be improved, particularly suitable for improving the light-emitting efficiency of light which is high in light energy and is easily absorbed by semiconductor materials, electrodes and the like and then converted into heat energy, for example, the improvement of the light-emitting efficiency of an ultraviolet light-emitting chip.

On the basis of the same inventive concept, the embodiments of the present disclosure further provide a method for manufacturing a light-emitting chip, including the following operations.

A first semiconductor layer, a first active layer and a second semiconductor layer are formed on a first side of a substrate in sequence; top surfaces of the first semiconductor layer, the first active layer, the second semiconductor layer and the substrate are located on a first horizontal plane and serve as light-emitting surfaces; and bottom surfaces of the first semiconductor layer, the first active layer, the second semiconductor layer and the substrate are located on a second horizontal plane.

A first electrode electrically connected with the first semiconductor layer and a second electrode electrically connected with the second semiconductor layer are manufactured, where the first electrode and the second electrode are disposed insulated from each other.

According to the light-emitting chip manufactured by the method for manufacturing the light-emitting chip, the first semiconductor layer, the first active layer, the second semiconductor layer and the substrate are disposed in a coplanar manner. Moreover, the top surfaces of the first semiconductor layer, the first active layer, the second semiconductor layer and the substrate directly serve as light-emitting surfaces, part of the generated light can be directly emitted out through the first semiconductor layer, the first active layer and the second semiconductor layer, so that an emission path of the part of light is shortened, absorption of light energy can be reduced to the maximum extent, and therefore, the light-emitting efficiency of the light-emitting chip can be improved.

### BRIEF DESCRIPTION OF THE DRAWINGS

FIG. 1 is a schematic structure diagram of an LED light-emitting chip in the related art.

FIG. 2 is a space diagram I of an epitaxial layer of a light-emitting chip provided by an embodiment of the present disclosure.

FIG. 3 is schematic diagram of a light-emitting direction of an epitaxial layer of a light-emitting chip as shown in FIG. 2.

FIG. 4 is a schematic plane diagram of an epitaxial layer of a light-emitting chip as shown in FIG. 2.

FIG. 5 is a schematic plane diagram of another epitaxial layer of a light-emitting chip provided by an embodiment of the present disclosure.

FIG. 6 is a space diagram II of an epitaxial layer of a light-emitting chip provided by an embodiment of the present disclosure.

FIG. 7 is a schematic plane diagram of an epitaxial layer of a light-emitting chip as shown in FIG. 6.

FIG. 8 is a space diagram III of an epitaxial layer of a light-emitting chip provided by an embodiment of the present disclosure.

FIG. 9 is a schematic diagram I of a manufacturing process of a single epitaxial layer of a light-emitting chip provided by another exemplary embodiment of the present disclosure.

FIG. 10 is a schematic diagram II of a manufacturing process of a single epitaxial layer of a light-emitting chip provided by another exemplary embodiment of the present disclosure.

FIG. 11 is a schematic diagram III of a manufacturing process of a single epitaxial layer of a light-emitting chip provided by another exemplary embodiment of the present disclosure.

FIG. 12 is a schematic diagram I of a batch manufacturing process of an epitaxial layer of a light-emitting chip provided by another exemplary embodiment of the present disclosure.

FIG. 13 is a schematic diagram II of a batch manufacturing process of an epitaxial layer of a light-emitting chip provided by another exemplary embodiment of the present disclosure.

FIG. 14 is a space diagram I of a light-emitting chip provided by still another exemplary embodiment of the present disclosure.

FIG. 15 is a schematic plane diagram of a light-emitting chip as shown in FIG. 14.

FIG. 16 is a space diagram II of a light-emitting chip provided by still another exemplary embodiment of the present disclosure.

FIG. 17 is a space diagram III of a light-emitting chip provided by still another exemplary embodiment of the present disclosure.

FIG. 18 is a schematic plane diagram of a light-emitting chip as shown in FIG. 17.

FIG. 19 is a schematic cross-sectional diagram of a connecting layer provided by still another exemplary embodiment of the present disclosure.

FIG. 20 is a space diagram IV of a light-emitting chip provided by still another exemplary embodiment of the present disclosure.

FIG. 21 is a space diagram V of a light-emitting chip provided by still another exemplary embodiment of the present disclosure.

FIG. 22 is a space diagram VI of a light-emitting chip provided by still another exemplary embodiment of the present disclosure.

FIG. 23 is a schematic plane diagram of a light-emitting chip as shown in FIG. 22.

FIG. 24 is a schematic flow chart of a manufacturing method of a light-emitting chip provided by another exemplary embodiment of the present disclosure.

FIG. 25 is a schematic diagram of a manufacturing process of a light-emitting chip provided by another exemplary embodiment of the present disclosure.

### DESCRIPTION OF REFERENCE SIGNS

11, first semiconductor layer; 12, first active layer; 13, second semiconductor layer; 14, substrate; 20, N-type semiconductor layer; 21, second conductive layer; 22, first conductive layer; 231, first insulating reflective layer; 232, second insulating reflective layer; 233, third insulating reflective layer; 24, connecting layer; 241, serrated protrusion; 30, active layer; 31, second electrode; 32, first electrode; 33, third electrode; 34, fourth electrode; 40, P-type semiconductor layer; 41, third semiconductor layer; 42, second active layer; 43, fourth semiconductor layer; 50, electrode; 61, temporary substrate; 62, photoresist layer; and 7, epitaxial layer of light-emitting chip.

### DETAILED DESCRIPTION OF THE EMBODIMENTS

In order to facilitate an understanding of the present disclosure, a more complete description of the present disclosure will now be made with reference to the associated drawings. Exemplary implementations of the present disclosure are given in the drawings. However, the present disclosure may be realized in many different forms and is not limited to the implementations described herein. Rather, the implementations are provided so that a more thorough and complete understanding of the content of the present disclosure is provided.

Unless otherwise defined, all technical and scientific terms used in the specification have a same meaning generally understood by a person having ordinary skill in the art to which the present disclosure belongs. The terms used in the specification of the present disclosure herein are for the purpose of describing the exemplary implementations only and are not intended to be limiting of the present disclosure.

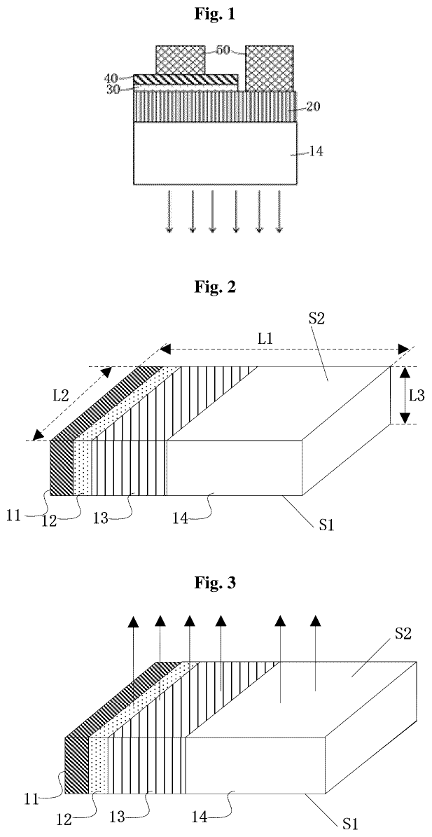

In the related art, a typical inverted LED chip structure is shown in FIG. 1, including a substrate 14, an N-type semiconductor layer 20, an active layer 30 and a P-type semiconductor layer 40 which are stacked in sequence from bottom to top, and two electrodes 50 which are respectively disposed on the N-type semiconductor layer 20 and the P-type semiconductor layer 40. The light-emitting direction is shown as an arrow in FIG. 1, the generated light at least needs to penetrate through the N-type semiconductor layer 20 and the substrate 14 to be emitted out, the transmission path of the light is long, energy attenuation is large, improvement of light-emitting efficiency is not facilitated, and especially, for an ultraviolet light-emitting chip, ultraviolet light is high in energy and is easily absorbed by semiconductor materials, electrodes, and the like, so that the light-emitting efficiency is low, which is also the main reason for the low light-emitting efficiency of the ultraviolet light-emitting chip.

Based on this, the present disclosure seeks to provide a solution capable of solving the above technical problem, the details of which will be set forth in the following embodiments.

The embodiments provide an epitaxial layer of a light-emitting chip, the epitaxial layer including, but not limited to, a first semiconductor layer, a first active layer, a second semiconductor layer and substrate.

The first semiconductor layer, the first active layer and the second semiconductor layer are located on a first side of the substrate, namely, the first semiconductor layer, the first active layer and the second semiconductor layer are located on the same side of the substrate. Moreover, top surfaces of the first semiconductor layer, the first active layer, the second semiconductor layer and the substrate are located on a first horizontal plane, and bottom surfaces of the first semiconductor layer, the first active layer, the second semiconductor layer and the substrate are located on a second horizontal plane, namely, in the embodiment, the first semiconductor layer, the first active layer, the second semiconductor layer and the substrate are disposed in a coplanar manner, but not stacked in sequence from top to bottom as shown in FIG. 1. In the embodiment, the top surfaces of the first semiconductor layer, the first active layer, the second semiconductor layer and the substrate directly serve as light-emitting surfaces, part of the generated light can be directly emitted out through the first semiconductor layer, the first active layer and the second semiconductor layer, so that an emission path of the part of light is shortened, absorption of light energy can be reduced to the maximum extent, and therefore, the light-emitting efficiency of the light-emitting chip can be improved, particularly suitable for improving the light-emitting efficiency of light which is high in light energy and is easily absorbed by semiconductor materials, electrodes and the like and then converted into heat energy, for example, the improvement of the light-emitting efficiency of an ultraviolet light-emitting chip.

It should be understood that in the embodiment, the materials of the first semiconductor layer, the first active layer, the second semiconductor layer and the substrate can be flexibly set according to requirements. For example, in an application example, when the epitaxial layer of the light-emitting chip is an epitaxial layer of an ultraviolet light-emitting chip, the first semiconductor layer may be, but not limited to, an AlₓGa₁₋ₓN layer, the first active layer may be, but not limited to, an Al_{y}Ga_{1-y}N/Al_{z}Ga_{1-z}N layer, and the second semiconductor layer may be, but not limited to, an AlₓGa₁₋ₓN layer.

In the embodiment, in order to further shorten the light-emitting path and reduce the absorption of the semiconductor layers and the like to light energy as much as possible, in the embodiment, a height L3 between the bottom surfaces and the top surfaces of the first semiconductor layer, the first active layer, the second semiconductor layer and the substrate is set to be greater than or equal to 0.3 micron and smaller than or equal to 15 microns, for example, may be specifically set as 0.3 micron, 0.5 micron, 1 micron, 3 microns, 5 microns, 7 microns, 9 microns, 10 microns, 13 microns, 15 microns, or the like according to requirements. Of course, L3 in the embodiment is not limited to the size of the above example, and may be equally replaced with other sizes according to application requirements. For ease of understanding, the embodiment will be described below with the epitaxial layer of the light-emitting chip shown in FIGS. 2-4 as an example.

With reference to the epitaxial layer of the light-emitting chip shown in FIGS. 2-4, the epitaxial layer of the light-emitting chip includes a first semiconductor layer 11, a first active layer 12, a second semiconductor layer 13 and a substrate 14, where the top surfaces S2 of the first semiconductor layer 11, the first active layer 12, the second semiconductor layer 13 and the substrate 14 are located on a first horizontal plane, and the bottom surfaces S1 of the first semiconductor layer 11, the first active layer 12, the second semiconductor layer 13 and the substrate 14 are located on a second horizontal plane, namely, the first semiconductor layer 11, the first active layer 12, the second semiconductor layer 13 and the substrate 14 are disposed in a coplanar manner. As shown in FIG. 3, the top surfaces S2 of the first semiconductor layer 11, the first active layer 12, the second semiconductor layer 13 and the substrate 14 serve as light-emitting surfaces, a part of light can be directly emitted out through the top surfaces S2 of the first semiconductor layer 11, the first active layer 12 and the second semiconductor layer 13, as shown in FIG. 3, the light-emitting path is shorter than that of the light in FIG. 1, and less light energy is absorbed by the light in the transmission process, so that the light-emitting efficiency is higher.

As shown in FIG. 2, the height between the bottom surface S1 and the top surface S2 of the first semiconductor layer 11, the first active layer 12, the second semiconductor layer 13 and the substrate 14 is denoted by L3 in FIG. 2. The value of L3 may be set to be greater than or equal to 0.3 micron and smaller than or equal to 15 microns according to requirements, so that it can be further guaranteed that the light-emitting path is short enough, and the light-emitting efficiency is guaranteed.

In some examples of the present example, to ensure the light-emitting area, referring to FIG. 2, the first semiconductor layer 11, the first active layer 12, the second semiconductor layer 13, and the substrate 14 may be set to have the same length L2, and L2 is greater than or equal to a product of L3 and 2. For example, the value of L2 may be, but is not limited to, greater than or equal to 0.6 micron and smaller than or equal to 30 microns, and specifically may be flexibly set according to requirements. Of course, in some examples, the length L2 of the first semiconductor layer 11, the first active layer 12, the second semiconductor layer 13 and the substrate 14 may also be set to be different or partially different according to requirements. For example, in some examples, the length L2 of the first semiconductor layer 11 may be set to be smaller than the length L2 of the second semiconductor layer 13. The lengths of other layer structures may also be flexibly changed according to requirements, and no more elaboration will be made herein.

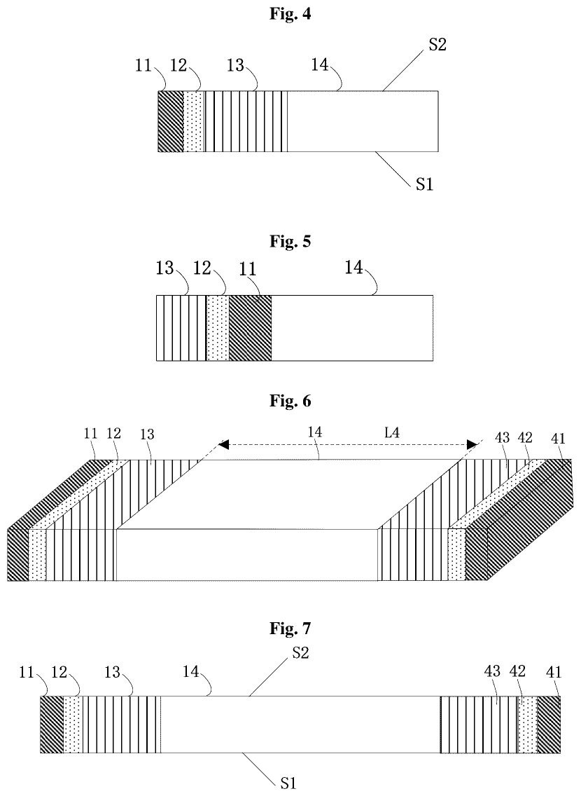

In some examples of the present example, to ensure the light-emitting area, as shown in FIG. 2, the total width L1 of the first semiconductor layer 11, the first active layer 12, the second semiconductor layer 13 and the substrate 14 may be set to be greater than or equal to L3. In the embodiment, the total width L1 of the first semiconductor layer 11, the first active layer 12, the second semiconductor layer 13 and the substrate 14 is the total width in the stacking direction after the first semiconductor layer 11, the first active layer 12, the second semiconductor layer 13 and the substrate 14 are stacked. For example, as shown in FIG. 4, in some examples of the embodiment, the first semiconductor layer 11 may be a P-type semiconductor layer, and the second semiconductor layer 13 may be an N-type semiconductor layer. In FIG. 4, the first semiconductor layer 11, the first active layer 12 and the second semiconductor layer 13 are disposed on the left side of the substrate 14, and the first semiconductor layer 11, the first active layer 12, the second semiconductor layer 13 and the substrate 14 are stacked in sequence from left to right. Of course, in the embodiment, the specific positions of the first semiconductor layer 11 and the second semiconductor layer 13 may also be flexibly switched according to requirements, for example, as shown in FIG. 5, the positions of the first semiconductor layer 11 and the second semiconductor layer 13 are switched with respect to FIG. 4.

In another example of the embodiment, in order to improve the light-emitting amount of the epitaxial layer of the light-emitting chip, as shown in FIGS. 6-7, the epitaxial layer of the light-emitting chip further includes, but is not limited to, a third semiconductor layer 41, a second active layer 42 and a fourth semiconductor layer 43 which are located on a second side of the substrate 14, the top surfaces S2 of the third semiconductor layer 41, the second active layer 42 and the fourth semiconductor layer 43 are located on a first horizontal plane, and the bottom surfaces S1 of the third semiconductor layer 41, the second active layer 42 and the fourth semiconductor layer 43 are located on a second horizontal plane. The first side and the second side of the substrate 14 are two opposite sides of the substrate. For example, in FIG. 6, the first side of the substrate 14 is the left side of the substrate 14, and the second side of the substrate 14 is the right side of the substrate 14. Compared with the light-emitting amount of the epitaxial layer of the light-emitting chip shown in FIGS. 2-5, the light-emitting amount of the epitaxial layer of the light-emitting chip shown in FIGS. 6-7 can be greatly improved, so that the brightness of the epitaxial layer of the light-emitting chip is promoted, and the high-brightness application requirement can be better met.

It is to be understood that in the embodiment, the type of the third semiconductor layer 41 may be the same as that of the first semiconductor layer 11, the type of the fourth semiconductor layer 43 may be the same as that of the second semiconductor layer 13, and the type of the second active layer 42 may be the same as that of the first active layer 12. In such a case, the semiconductor layers and the active layers which are disposed on the left side and the right side of the substrate 14 are symmetrically disposed. Of source, adjustment may be made flexibly according to requirements, for example, the type of the third semiconductor layer 41 may be set to be the same as that of the second semiconductor layer 13 according to requirements, the type of the fourth semiconductor layer 43 may be the same as that of the first semiconductor layer 11, and the type of the second active layer 42 may be the same or not the same as that of the first active layer 12. In addition, in the example, the length LA of the substrate 14 may be appropriately set according to requirements, so that the light-emitting area is increased while the light-emitting amount is guaranteed. For example, L4 may be set to be greater than or equal to a product of L3 and 2.

Of course, in the embodiment, corresponding semiconductor layers and active layers may also be disposed on other sides of the substrate 14 according to requirements, for example, corresponding semiconductor layers and active layers may be disposed on at least one of a third side and a fourth side between the first side and the second side of the substrate 14 in an arrangement manner similar to that shown in FIG. 7, which will not be described in detail herein.

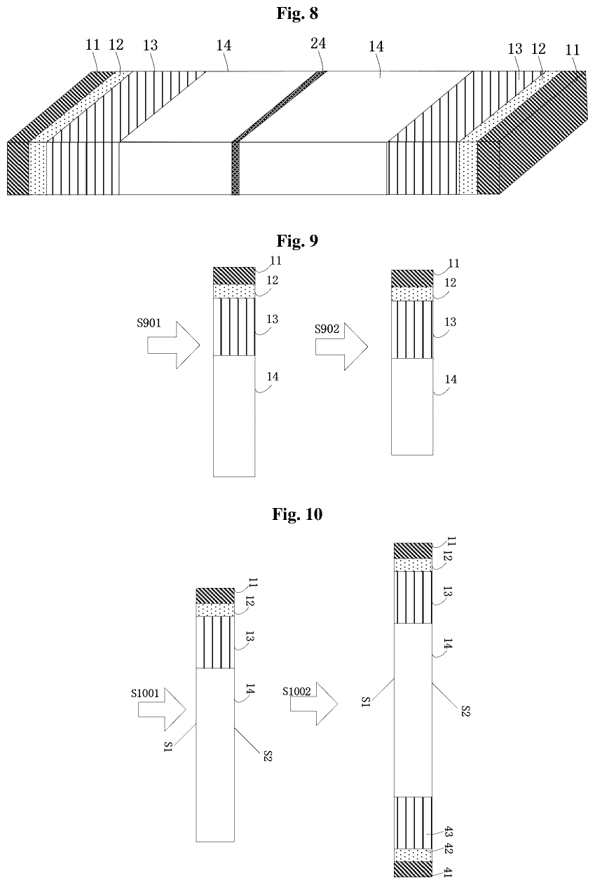

In another example of the embodiment, in order to increase the light-emitting amount of the epitaxial layer of the light-emitting chip, epitaxial layers of at least two light-emitting chips shown in FIG. 2 may be spliced together to form a spliced epitaxial layer of a light-emitting chip with greater light-emitting amount as shown in FIG. 7. For example, an example of a spliced epitaxial layer of a light-emitting chip is shown in FIG. 8, and second sides of the substrates 14 of the two epitaxial layers of the light-emitting chip are spliced together in a bilateral symmetry manner through a connecting layer 24, thereby forming a spliced epitaxial layer of a light-emitting chip with larger light-emitting surface and larger light-emitting amount. The connecting layer 24 in the embodiment may have a light-transmitting property or also may be set to have no light-transmitting property according to requirements, and may be flexibly arranged according to application requirements. In the example, the semiconductor layers and the active layers on two sides of the two substrates are in one-to-one correspondence. Of source, with reference to the example of FIG. 7, the semiconductor layers and the active layers may also be set to be not in one-to-one correspondence.

In addition, in the embodiment, the number of the symmetrically spliced epitaxial layers of the light-emitting chip may also be flexibly set according to requirements and is not limited to two shown in FIG. 7. For example, four epitaxial layers of the light-emitting chip, six epitaxial layers of the light-emitting chip or eight epitaxial layers of the light-emitting chip may be spliced according to requirements to obtain the spliced epitaxial layer of the light-emitting chip.

Therefore, in the epitaxial layer of the light-emitting chip provided by the embodiment, the first semiconductor layer, the first active layer, the second semiconductor layer and the substrate included are disposed in a coplanar manner and not stacked vertically. Moreover, the top surfaces of the first semiconductor layer, the first active layer, the second semiconductor layer and the substrate serve as light-emitting surfaces, part of the generated light can be directly emitted out through the first semiconductor layer, the first active layer and the second semiconductor layer, so that an emission path of the part of light is shortened, absorption of light energy can be reduced to the maximum extent, and therefore, the light-emitting efficiency of the light-emitting chip can be improved, particularly suitable for improving the light-emitting efficiency of light which is high in light energy and is easily absorbed by semiconductor materials, electrodes and the like and then converted into heat energy, for example, the improvement of the light-emitting efficiency of an ultraviolet light-emitting chip. For an application scenario requiring a large light-emitting amount, corresponding semiconductor layers can be disposed on both the first side and the second side of the substrate, or at least two epitaxial layers of the light-emitting chip are spliced to obtain the epitaxial layer of the light-emitting chip with a larger light-emitting amount, so that the application scenario of the epitaxial layer of the light-emitting chip is wider.

### ANOTHER EXEMPLARY EMBODIMENT

For ease of understanding, the embodiment will be described below with a method for manufacturing an epitaxial layer of a light-emitting chip as an example. In the embodiment, the manufacturing of the epitaxial layer of the light-emitting chip includes: a first semiconductor layer, a first active layer and a second semiconductor layer are formed on a first side of a substrate; top surfaces of the first semiconductor layer, the first active layer, the second semiconductor layer and the substrate are located on a first horizontal plane and serve as light-emitting surfaces; and bottom surfaces of the first semiconductor layer, the first active layer, the second semiconductor layer and the substrate are located on a second horizontal plane. For example, when the epitaxial layer of the light-emitting chip shown in FIG. 2 is manufactured, the manufacturing process is shown in FIG. 9, which includes, but is not limited to, the following operations.

At S901, a second semiconductor layer 13, a first active layer 12 and a first semiconductor layer 11 are formed on the first side of a substrate 14.

In the embodiment, the second semiconductor layer 13, the active layer 12 and the first semiconductor layer 11 may be formed on the first side of the substrate 14 in sequence by, but not limited to, precipitation.

At S902, grinding and polishing treatment is carried out on the substrate 14 so as to reduce the thickness of the substrate 14, the total width L1 of the first semiconductor layer 11, the first active layer 12, the second semiconductor layer 13 and the substrate 14 may be adjusted according to application requirements through the adjustment of the degree of grinding and polishing so as to flexibly adjust the light-emitting area according to requirements. It should be understood that this operation is an optional operation.

For another example, when the epitaxial layer of the light-emitting chip shown in FIGS. 6-7 is manufactured, the manufacturing process is shown in FIG. 10, which includes, but is not limited to, the following operations.

At S1001, a second semiconductor layer 13, a first active layer 12 and a second semiconductor layer 11 are formed on the first side of the substrate 14.

At S1002, a fourth semiconductor layer 43, a second active layer 42 and a third semiconductor layer 41 are sequentially formed on the second side of the substrate 14.

In the example, prior to performing S1002, the substrate 14 may be subjected to grinding and polishing treatment to adjust the thickness of substrate 14 according to application requirements. In some examples, S1002 may also be performed before S1001, or S1001 and S1002 may be performed in parallel.

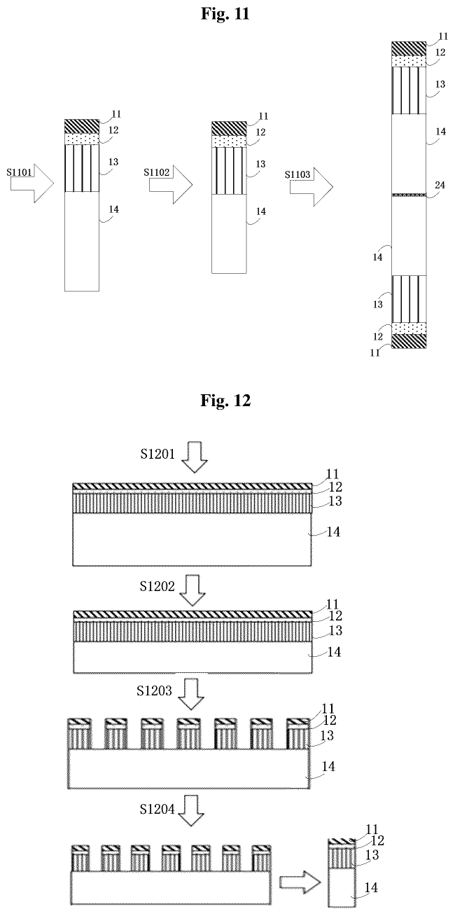

For another example, when the epitaxial layer of the light-emitting chip shown in FIG. 8 is manufactured, the manufacturing process is shown in FIG. 11, which includes, but is not limited to, the following operations.

At S1101, a second semiconductor layer 13, a first active layer 12 and a second semiconductor layer 11 are formed on the first side of the substrate 14.

At S1102, grinding and polishing treatment is carried out on the substrate 14 to reduce the thickness of the substrate 14, and the total width L1 of the first semiconductor layer 11, the first active layer 12, the second semiconductor layer 13 and the substrate 14 may be adjusted according to application requirements through the adjustment of the degree of grinding and polishing.

At S1103, two manufactured epitaxial layers of the light-emitting chip are symmetrically spliced together through a connecting layer 24.

The above examples are described by taking the manufacturing process of the single epitaxial layer of the light-emitting chip as an example. It should be understood that when the epitaxial layer of the light-emitting chip is manufactured, the epitaxial layer can also be manufactured in batches. For example, the batch manufacturing process of the epitaxial layer of the light-emitting chip shown in FIG. 2 is shown in FIG. 12, and the batch manufacturing process includes, but is not limited to, the following operations.

At S1201, a second semiconductor layer 13, a first active layer 12 and a second semiconductor layer 11 are formed on the first side of the substrate 14.

At S1202, grinding and polishing treatment is carried out on the substrate 14 so as to reduce the thickness of the substrate 14, and the total width L1 of the first semiconductor layer 11, the first active layer 12, the second semiconductor layer 13 and the substrate 14 may be adjusted according to application requirements through the adjustment of the degree of grinding and polishing.

At S1203, photoetching and etching process treatment is carried out on the first semiconductor layer 11, the first active layer 12 and the second semiconductor layer 13 on the substrate 14 so as to form an epitaxial layer array on the first side of the substrate 14.

At S1204, the epitaxial array is subjected to a scribing and splitting process along the channel of the epitaxial array to obtain a plurality of single epitaxial layers of a light-emitting chip.

For batch manufacturing of the epitaxial layer of the light-emitting chip shown in FIGS. 6 to 7, a corresponding fourth semiconductor layer 43, a second active layer 42, and a third semiconductor layer 41 are also formed on the second side of the substrate 14 before S1203, which is not repeated here.

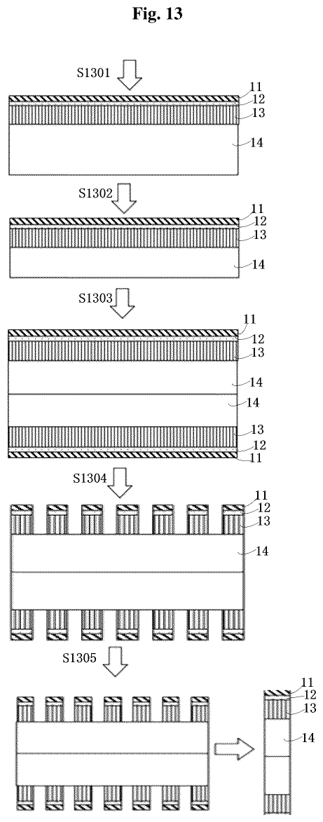

For another example, the batch manufacturing process of the epitaxial layer of the light-emitting chip shown in FIG. 8 is to shown in FIG. 13, and the batch manufacturing process includes, but is not limited to, the following operations.

At S1301, a second semiconductor layer 13, a first active layer 12 and a second semiconductor layer 11 are formed on the first side of the substrate 14.

At S1302, grinding and polishing treatment is carried out on the substrate 14 so as to reduce the thickness of the substrate 14, the total width L1 of the first semiconductor layer 11, the first active layer 12, the second semiconductor layer 13 and the substrate 14 may be adjusted according to application requirements through the adjustment of the degree of grinding and polishing.

At S1303, two substrates 14 are symmetrically spliced together through a connecting layer 24.

At S1304, photoetching and etching process treatment is carried out on the first semiconductor layer 11, the first active layer 12 and the second semiconductor layer 13 on two sides of the two substrates 14 so as to form an epitaxial layer array on the first side of the substrate 14.

At S1305, the epitaxial array is subjected to a scribing and splitting process along the channel of the epitaxial array to obtain a plurality of single epitaxial layers of the light-emitting chip as shown in FIG. 8.

Therefore, the manufacturing process of the epitaxial array of the light-emitting chip provided by the embodiment is simple, efficient and low in cost. Moreover, in the manufactured epitaxial array of the light-emitting chip, the first semiconductor layer, the first active layer, the second semiconductor layer and the substrate are disposed in a coplanar manner, the top surfaces of the first semiconductor layer, the first active layer, the second semiconductor layer and the substrate directly serve as light-emitting surfaces, part of the generated light can be directly emitted out through the first semiconductor layer, the first active layer and the second semiconductor layer, so that an emission path of the part of light is shortened, absorption of light energy can be reduced to the maximum extent, and therefore, the light-emitting efficiency of the light-emitting chip can be improved. The method is especially suitable for manufacturing the epitaxial layer of the ultraviolet light chip.

### ANOTHER EXEMPLARY EMBODIMENT

The embodiment provides a light-emitting chip, which may be an ultraviolet light-emitting chip, and also may be a blue light-emitting chip, a green light-emitting chip, a red light-emitting chip or the like. The light-emitting chip provided by the embodiment may be a forward light-emitting chip, an inverted light-emitting chip or a vertical light-emitting chip. The light-emitting chip provided by the embodiment can be a micron-sized light-emitting chip (namely a micro light-emitting chip), for example, can include, but not limited to, a Mini LED chip and a Micro LED chip, and can also be a light-emitting chip larger than the micron-sized light-emitting chip, for example, a common-sized light-emitting chip or a large-sized light-emitting chip.

The light-emitting chip provided by an example of the embodiment includes the epitaxial layer of the light-emitting chip as shown in FIG. 2 or FIG. 5, and further includes a first electrode electrically connected with the first semiconductor layer and a second electrode electrically connected with the second semiconductor layer, and the first electrode and the second electrode are disposed insulated from each other. The first semiconductor layer, the first active layer, the second semiconductor layer and the substrate of the epitaxial layer of the light-emitting chip are disposed in a coplanar manner. Moreover, the top surfaces of the first semiconductor layer, the first active layer, the second semiconductor layer and the substrate serve as light-emitting surfaces, part of the generated light can be directly emitted out through the first semiconductor layer, the first active layer and the second semiconductor layer, so that an emission path of the part of light is shortened, absorption of light energy can be reduced to the maximum extent, and therefore, the light-emitting efficiency of the light-emitting chip can be improved, particularly, the light-emitting efficiency of the ultraviolent light-emitting chip can be improved.

In an application scenario of the embodiment, in order to further improve the light-emitting efficiency of the light-emitting chip, the first electrode and the second electrode of the light-emitting chip are respectively disposed on a bottom surface of the epitaxial layer of the light-emitting chip, and the bottom surface of the epitaxial layer of the light-emitting chip here consists of the bottom surfaces of the first semiconductor layer, the first active layer, the second semiconductor layer and the substrate (as shown by S1 in FIG. 2). Of course, in other application scenarios, at least one of the first electrode and the second electrode may also be disposed on the top surface of the epitaxial layer of the light-emitting chip (as shown by S2 in FIG. 2).

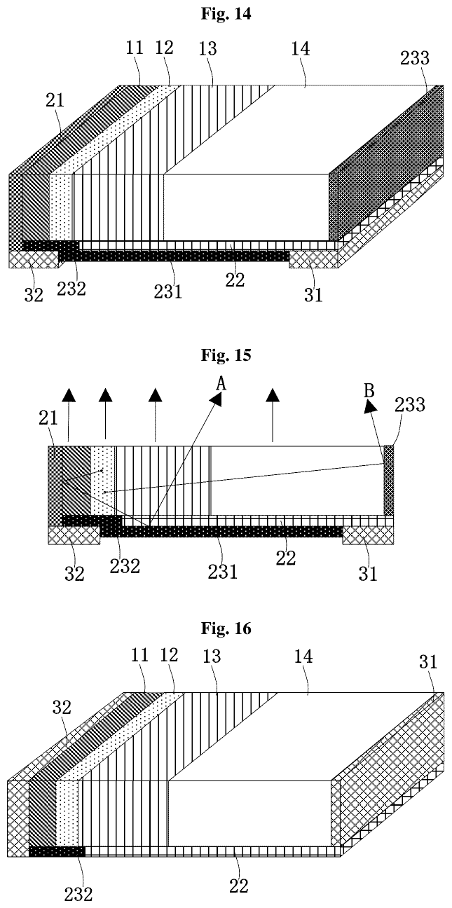

For ease of understanding, the embodiment will be described below with the light-emitting chip shown in FIG. 14 as an example. Referring for FIG. 14, the light-emitting chip include the epitaxial layer of the light-emitting chip as shown in FIG. 2, where the first semiconductor layer 11 is a P-type semiconductor layer, the second semiconductor layer 13 is an N-type semiconductor layer, and the first electrode and the second electrode are disposed on a bottom surface of the epitaxial layer of the light-emitting chip. The light-emitting chip further includes a first conductive layer 22 located between the bottom surfaces of the second semiconductor layer 13 and the substrate 14 and the second electrode 31 and a second conductive layer 21 attaching to the outer side surface of the first semiconductor layer 11, and one end, close to the bottom surface of the epitaxial layer of the light-emitting chip, of the second conductive layer 21 is in contact with the first electrode 32. Referring to FIG. 14, the outer side surface of the first semiconductor layer 11 in the example includes: at least one side surface that is located between the top surface and the bottom surface of the first semiconductor layer 11 and exposed to the outside, for example, including, but not limited to, the left side surface of the first semiconductor layer 11 in FIG. 14, and the right side surface of the first semiconductor layer 11 attaches to the first active layer 12. It should be understood that the positions of the first electrode 32 and the second electrode 31 specifically disposed on a bottom surface of the epitaxial layer of the light-emitting chip in the embodiment can be flexibly disposed, and no more elaboration will be made herein.

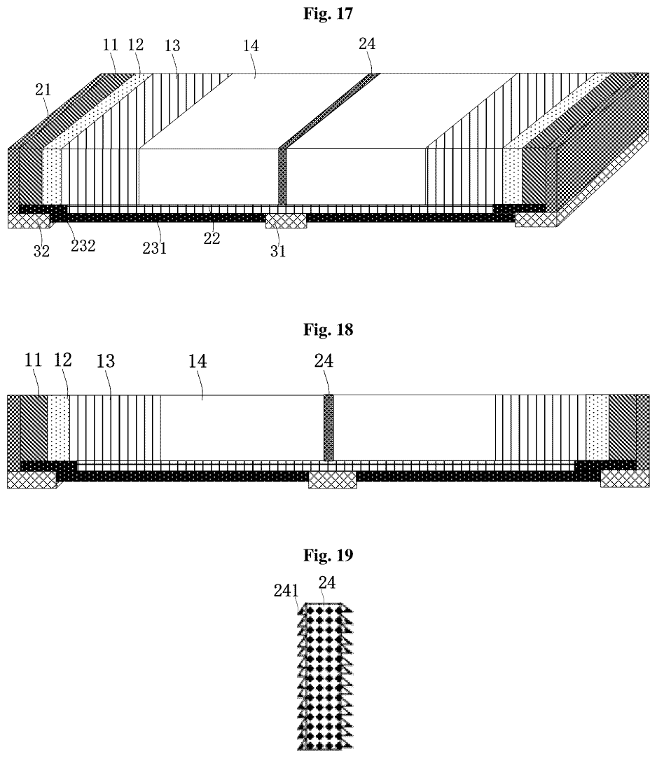

Of course, in some application examples, at least one of the first electrode 32 and the second electrode 31 may also be disposed on the side surface, for example, as shown in FIG. 16, the first electrode 32 may be disposed on the left side surface of the first conductive layer 22, the second electrode 31 may be disposed on the side surface of the second side of the substrate 14 (the right side surface of the substrate 14 in the figure), in such a case, with respect to the manner in which the electrodes are disposed on the top surface S2, the light-emitting efficiency can also be improved.

In the embodiment, in order to further improve the light-emitting efficiency of the light-emitting chip, at least one of the first conductive layer 22 and the second conductive layer 21 may be set to be as a reflective layer, so that light emitted to the first conductive layer 22 or the second conductive layer 21 can be reflected and further emitted from the top surface. For example, in an application scenario, the second conductive layer 21 may be set as a reflective layer, in order to enhance the reflection effect, the surface of the second conductive layer 21 may also be set as a rough surface, the surface including a surface in contact with the first semiconductor layer 11, and in some examples, only this surface may also be set as a rough surface, and the other surfaces of the second conductive layer 21 may be set as smooth surfaces.

In order to further improve the light-emitting efficiency of the light-emitting chip, in some other application scenarios of the embodiment, as shown by FIG. 14, the light-emitting chip may further include, but is not limited to, at least one of the following:
a first insulating reflective layer 231, which is disposed on a surface, away from the epitaxial layer of the light-emitting chip, of the first conductive layer 22, for example, the first insulating reflective layer 231 can attach to the bottom surface of the first conductive layer 22, so that light emitted to the bottom surface of the first conductive layer 22 is reflected toward the light-emitting surface, thereby improving the light-emitting efficiency.
a second insulating reflective layer 232, which is disposed on bottom surfaces of the first semiconductor layer 11 and the first active layer 12, for example, the second insulating reflective layer 232 can attach to the bottom surfaces of the first semiconductor layer 11 and the first active layer 12, so that light emitted to the first semiconductor layer 11 and the first active layer 12 is reflected toward the light-emitting surface, thereby improving the light-emitting efficiency.
a third insulating reflective layer 233, which disposed on the side surface of the second side of the substrate 14, for example, the third insulating reflective layer 233 can attach to side surface of the second side of the substrate 14, so as to reflect the light emitted to the side surface of the second side of the substrate 14 is reflected toward the light-emitting surface, thereby improving the light-emitting efficiency.

It should be understood that the first insulating reflective layer 231, the second insulating reflective layer 232 and the third insulating reflective layer 233 of the above examples can be flexibly combined and disposed according to requirements, and the details of specific combination modes are not repeated herein.

In some application scenarios, in order to further improve the light-emitting efficiency, at least one of the first electrode 32 and the second electrode 31 may also be provided as an electrode layer having a reflective characteristic.

Referring to FIG. 15, through the arrangement of the first insulating reflective layer 231, the second insulating reflective layer 232 and the third insulating reflective layer 233, a light beam A emitted on the bottom surface of the first conductive layer 22 can be emitted out from the light-emitting surface after being reflected, a light beam B emitted on the side surface of the second side of the substrate 14 can be reflected toward the light-emitting surface after being reflected, and a part of the light beam can be directly emitted from the first semiconductor layer 11, the first active layer 12 and the second semiconductor layer 13, so that the light-emitting efficiency can be further improved.

The light-emitting chip provided by another example of the embodiment includes the epitaxial layer of the light-emitting chip shown in FIG. 8, that is, the light-emitting chip includes two epitaxial layers of the light-emitting chip shown in FIG. 2 or FIG. 5, and second sides of the substrates of the two epitaxial layers of the light-emitting chip are spliced together in a left-right symmetry manner through a connecting layer. A light-emitting chip structure of an example is shown in FIGS. 17 to 18, the side surfaces of the second sides of the two substrates 14 are spliced together by a connecting layer 24, and the connecting layer 24 may be, but is not limited to, an adhesive layer with adhesive. The arrangement of the first insulating reflective layer 231, the second insulating reflective layer 232, the first conductive layer 22, and the second conductive layer 21 illustrated in FIG. 17 is referred to the above-described example and will not be repeated here. The number of the first electrodes 32 illustrated in FIG. 17 is two, or only one according to requirements as long as the first electrodes 32 are electrically connected to the two first semiconductor layers 11 corresponding to both sides of the substrate 14. Similarly, the number of the second electrode 31 can also be flexibly set and will not be repeated here.

In the light-emitting chip illustrated in FIGS. 17-18, the light-emitting surface and light-emitting area are larger respect to the light-emitting chip shown in FIGS. 14-16 due to use of the spliced epitaxial layer of the light-emitting chip. In some application examples, at least one of two side surfaces of connecting layer 24, which are in contact with two substrates respectively, may be disposed as a reflective surface capable of reflecting light in order to further improve the light-emitting efficiency and light-emitting effect, and the reflective surface may be further provided as a reflective rough surface in order to improve the reflection effect. The rough surface in the embodiment can be realized by providing raised portions and/or recessed portions. For example, in an example, the reflective rough surface may be, but is not limited to, a serrated surface provided with serrated protrusions, and in order to improve the reflection effect, inclined surfaces of the serrated protrusions face the top surface of the substrate. For example, referring to the schematic diagram of the interface of the connecting layer 24 shown in FIG. 19, two surfaces, in contact with two side surfaces of the two substrates 14, of the connecting layer 24 are reflective rough surfaces, and the inclined surfaces of the serrated protrusions 241 on the reflective rough surfaces face the top surfaces of the substrates 14. Of course, it should be understood that the serrated protrusions 241 may be equally replaced with protrusions or recessed portions of other shapes, and no more elaboration will be made herein.

In addition, it should be understood that a surface, close to the substrate 14, of the first insulating reflective layer 231 and a surface, close to the first active layer 12, of the second insulating reflective layer 232 in the embodiment may be provided as rough surfaces according to requirements, and no more elaboration will be made herein.

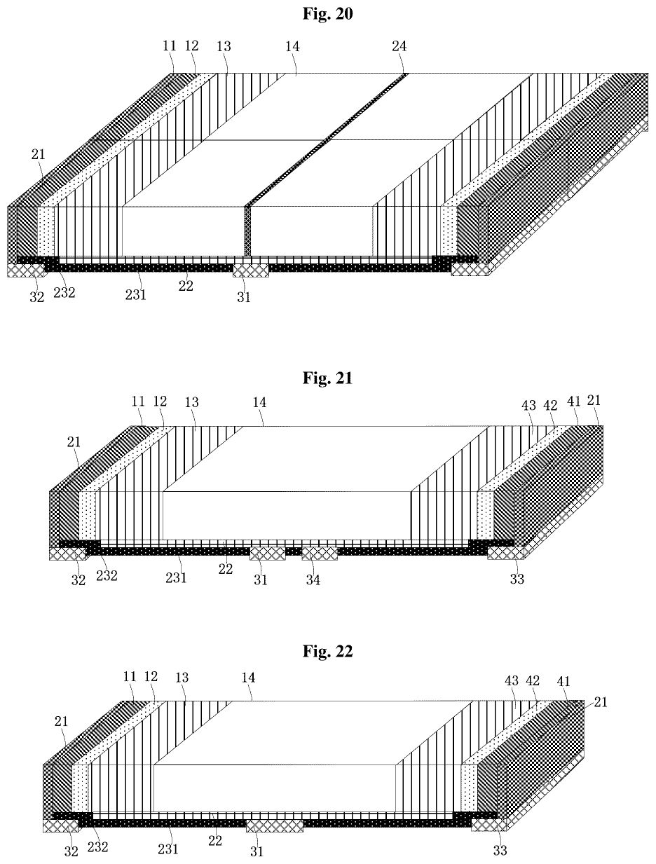

It should be understood that when the light-emitting chip adopts the spliced epitaxial layer of the light-emitting chip, the spliced epitaxial layer of the light-emitting chip is not limited to two as described in FIGS. 17-18, and may be provided as four as desired, for example, as shown in FIG. 20, the spliced epitaxial layer may be provided as six, eight, or ten as desired, and so forth, and no more elaboration will be made herein.

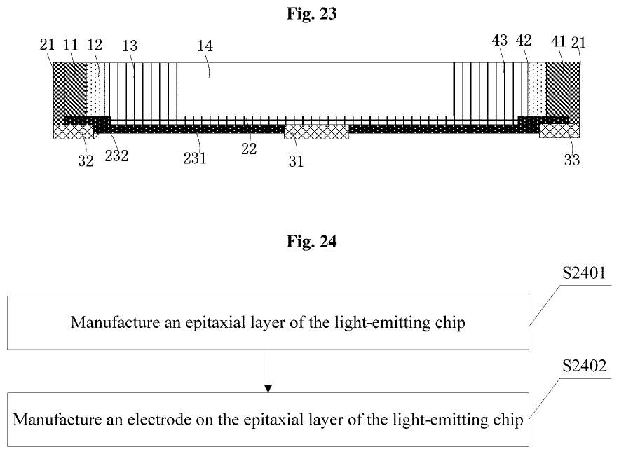

The light-emitting chip provided by another example of the embodiment includes the epitaxial layer of the light-emitting chip as shown in FIGS. 6-7, namely, respect to the light-emitting chip described in FIGS. 14-15, the light-emitting chip described by the example further includes a third semiconductor layer, a second active layer and a fourth semiconductor layer which are located on the second side of the substrate, a third electrode electrically connected with the third semiconductor layer and a fourth electrode electrically connected with the fourth semiconductor layer, and the third electrode is disposed insulated from the fourth electrode and the second electrode, and the fourth electrode and the first electrode are disposed insulated from each other. A light-emitting chip structure of an example is shown in FIG. 21 and includes a substrate 14, a first semiconductor layer 11, a first active layer 12, and a second semiconductor layer 13 disposed on a first side of the substrate 14, and a third semiconductor layer 41, a second active layer 42, and a fourth semiconductor layer 43 disposed on a second side of the substrate 14. In FIG. 21, a third electrode 33 electrically connected to the third semiconductor layer 41 and a fourth electrode 34 electrically connected to the fourth semiconductor layer 43 are included in addition to the first electrode 32 and the second electrode 31. It should be understood that when the first semiconductor layer 11 and the third semiconductor layer 41 are of the same type, only one of the third electrode 33 and the first electrode 32 may remain and are electrically connected to the first semiconductor layer 11 and the third semiconductor layer 41, respectively, the second electrode 31 and the fourth electrode 34 are disposed similarly, for example, as shown in FIGS. 22 to 23, when the second semiconductor layer 13 and the fourth semiconductor layer 43 are the same in type, only one second electrode 31 may be provided, which is electrically connected to the second semiconductor layer 13 and the fourth semiconductor layer 43, respectively, through the first conductive layer 22. The integrity of the light-emitting chip shown in the embodiment is better than that of the light-emitting chip shown in FIGS. 17-18, and the light-emitting area and the light-emitting amount of the two are equivalent. In some examples, in the light-emitting chip shown in FIGS. 21-23, corresponding semiconductor layers and active layers may also be provided on at least one of a third side and a fourth side between first side and second side of the substrate 14 as required to further increase the light-emitting amount, and size of substrate 14 may also be increased by appropriate amount as required to increase the light-emitting area at same time

Therefore, the light-emitting chip provided by the embodiment can be but not limited to an ultraviolet light-emitting chip, the light-emitting efficiency of the light-emitting chip is higher than that of the light-emitting chip shown in FIG. 1. Moreover, the light-emitting amount and the light-emitting area of the light-emitting chip can be adjusted according to requirements, the light-emitting chip can be better applied to scenarios with various requirements, and the applicability is better.

### ANOTHER EXEMPLARY EMBODIMENT

For ease of understanding, the embodiment will be described below with the manufacturing process of the light-emitting chip as an example. In the embodiment, the manufacturing method of the light-emitting chip is shown in FIG. 24, and includes, but is not limited to, the following operations.

At S2401, an epitaxial layer of the light-emitting chip is manufactured. The method for manufacturing the epitaxial layer of the light-emitting chip in the embodiment can adopt, but is not limited to, the method shown in the above embodiment, and will not be repeated herein

At S2402, an electrode is manufactured on the epitaxial layer of the light-emitting chip.

For example, when the epitaxial layer of the light-emitting chip manufactured by the method shown in the embodiment is the epitaxial layer of the light-emitting chip shown in FIGS. 2-5 or FIG. 8 (where when the epitaxial layer of the light-emitting chip shown in FIG. 8 is manufactured, before S2402, second sides of the substrates of the two epitaxial layers of the light-emitting chip are spliced together in a bilateral symmetry manner through a connecting layer), a first electrode electrically connected with the first semiconductor layer and a second electrode electrically connected with the second semiconductor layer are manufactured on the epitaxial layer of the light-emitting chip, and the first electrode and the second electrode are disposed in an insulated manner.

When the epitaxial layer of the light-emitting chip manufactured by the method shown in the embodiment is the epitaxial layer of the light-emitting chip shown in FIGS. 6-7, a first electrode and/or a third electrode electrically connected with the first semiconductor layer and the third electrode and a second electrode and/or a fourth electrode electrically connected with the second semiconductor layer and the fourth semiconductor layer are manufactured on the epitaxial layer of the light-emitting chip.

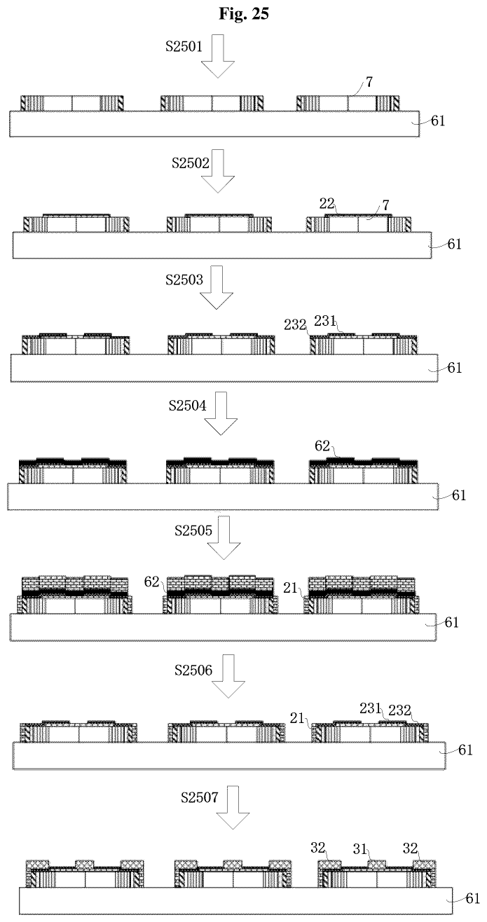

For ease of understanding, a process for manufacturing the light-emitting chip will be described below with the epitaxial layer of the light-emitting chip shown in FIG. 8 as an example. As shown in FIG. 25, the process includes, but is not limited to, the following operations.

At S2501, the independent epitaxial layer 7 of the light-emitting chip is transferred to a temporary substrate 61. In some examples, in a splitting operation for manufacturing the epitaxial layer 7 of the light-emitting chip, the independent epitaxial layer 7 of the light-emitting chip obtained by completing splitting can be transferred to the temporary substrate 61 while splitting is performed, so as to improve the manufacturing efficiency.

At S2502, a first conductive layer 22 is formed on a corresponding area on the bottom surface of the epitaxial layer 7 of the light-emitting chip.

In an example, the first conductive layer 22, may be deposited by, but not limited to, masking and photolithography processes on a corresponding area on the bottom surface of the epitaxial layer 7 of the light-emitting chip, and the first conductive layer 22 is electrically connected to the second semiconductor layer and insulated from the first semiconductor layer.

At S2503, a first insulating reflective layer 231 and a second insulating reflective layer 232 are formed on corresponding areas on the bottom surface of the epitaxial layer 7 of the light-emitting chip.

In an example, the first insulating reflective layer 231 and the second insulating reflective layer 232, may be deposited by, but not limited to, masking and photolithography processes on a corresponding area on the bottom surface of the epitaxial layer 7 of the light-emitting chip, and a window for providing the second electrode is reserved in the first conductive layer 22.

At S2504, a photoresist layer 62 is coated on the bottom surface of the epitaxial layer 7 of the light-emitting chip and patterning is carried out, so that one end, facing the bottom surface, of the first semiconductor layer of the epitaxial layer 7 of the light-emitting chip is exposed out of the photoresist layer 62.

At S2505, a second conductive layer 21 is manufactured on the outer side surface of the first semiconductor layer.

For example, in an example, the second conductive layer 21 may be manufactured on the outer side surface of the first semiconductor layer by a photolithography process and an Atomic layer deposition (ALD) process.

At S2506, the photoresist layer 62 is removed.

At S2507, a first electrode 32 and a second electrode 31 are manufactured on the bottom surface of epitaxial layer 7 of the light-emitting chip.

For example, in an example, the first electrode 32 and the second electrode 31 may be manufactured on the epitaxial layer 7 of the light-emitting chip by, but not limited to, an evaporation or sputtering process to form the light-emitting chip. Each prepared light-emitting chip can be separated from the temporary substrate 61 according to requirements, or can be directly sent to the next procedure without being separated.

It is to be understood that the lithography process, the ALD process, the evaporation or sputtering process and the like involved in the above operations are merely exemplary illustrations, and those having ordinary skill in the art may employ other equivalent substitutions of processes capable of achieving the corresponding functions, which will not be repeated herein.

It should be understood that when the epitaxial layer of the light-emitting chip shown in FIGS. 2-5 is adopted to manufacture the light-emitting chip, the manufacturing process is similar to FIG. 25, except that the manufacturing process of third insulating reflective layer is optionally added as required. When the epitaxial layer of the light-emitting chip shown in FIGS. 6-7 is adopted to manufacture the light-emitting chip, the manufacturing process is similar to FIG. 25, which will not be repeated herein.

Therefore, the manufacturing process of the light-emitting chip provided by the embodiment is simple, efficient and low in cost, in the manufactured light-emitting chip, the semiconductor layer, the active layer, and the substrate included are disposed in a coplanar manner. Moreover, the top surfaces of the semiconductor layer, the active layer and the substrate serve as light-emitting surfaces, part of the generated light can be directly emitted out of the light-emitting surface through the semiconductor layer and the active layer, so that an emission path of the part of light is shortened, absorption of light energy can be reduced to the maximum extent, and therefore, the light-emitting efficiency of the light-emitting chip can be improved. The method is especially suitable for manufacturing the ultraviolet light chip or the deep ultraviolet light chip.

It is to be understood that the application of the present disclosure is not limited to the examples described above, and modifications or variations may be made in light of the above description by those of ordinary having ordinary skill in the art, all of which are intended to fall within the scope of the appended claims.

1. A light-emitting chip, comprising at least one epitaxial layer of a light-emitting chip, each epitaxial layer of the light-emitting chip comprising a first semiconductor layer, a first active layer, a second semiconductor layer and substrate, wherein
the first semiconductor layer, the first active layer and the second semiconductor layer are located on a first side of the substrate; top surfaces of the first semiconductor layer, the first active layer, the second semiconductor layer and the substrate are located on a first horizontal plane and serve as light-emitting surfaces; bottom surfaces of the first semiconductor layer, the first active layer, the second semiconductor layer and the substrate are located on a second horizontal plane;
the light-emitting chip further comprises a first electrode electrically connected with the first semiconductor layer and a second electrode electrically connected with the second semiconductor layer, and the first electrode and the second electrode are disposed insulated from each other;
a height L3 between the bottom surfaces and the top surfaces of the first semiconductor layer, the first active layer, the second semiconductor layer and the substrate is greater than or equal to 0.3 micron and smaller than or equal to 15 microns; and
lengths L2 of the first semiconductor layer, the first active layer, the second semiconductor layer and the substrate are the same, and L2 is greater than or equal to a product of L3 and 2.

2-3. (canceled)

4. The light-emitting chip according to claim 1, wherein a total width L1 of the first semiconductor layer, the first active layer, the second semiconductor layer and the substrate is greater than or equal to L3.

5. The light-emitting chip according to claim 1, wherein the epitaxial layer of the light-emitting chip further comprises a third semiconductor layer, a second active layer, and a fourth semiconductor layer which are located on a second side of the substrate, top surfaces of the third semiconductor layer, the second active layer, and the fourth semiconductor layer are located on the first horizontal plane, and bottom surfaces of the third semiconductor layer, the second active layer and the fourth semiconductor layer are located on the second horizontal plane; the first side and the second side are two opposite sides of the substrate.

6. The light-emitting chip according to claim 1, wherein the light-emitting chip comprises two epitaxial layers of the light-emitting chip, second sides of the substrates of the two epitaxial layers of the light-emitting chip are spliced together in a left-right symmetry manner through a connecting layer, and the first side and the second side are two opposite sides of the substrate.

7. The light-emitting chip according to claim 6, wherein the first electrode and the second electrode are respectively disposed on a bottom surface of the epitaxial layer of the light-emitting chip, and the bottom surface of the epitaxial layer of the light-emitting chip consists of the bottom surfaces of the first semiconductor layer, the first active layer, the second semiconductor layer and the substrate.

8. The light-emitting chip according to claim 5, wherein the light-emitting chip further comprises a third electrode electrically connected with the third semiconductor layer and a fourth electrode electrically connected with the fourth semiconductor layer, the third electrode is disposed insulated from the fourth electrode and the second electrode, and the fourth electrode and the first electrode are disposed insulated from each other.

9. The light-emitting chip according to claim 7, wherein the first semiconductor layer, the first active layer, the second semiconductor layer and the substrate are sequentially connected, the first semiconductor layer is a P-type semiconductor layer, and the second semiconductor layer is an N-type semiconductor layer;
the light-emitting chip further comprises a first conductive layer located between the bottom surfaces of the second semiconductor layer and the substrate and the second electrode and a second conductive layer attached to an outer side surface of the first semiconductor layer, and one end, close to the bottom surface of the epitaxial layer of the light-emitting chip, of the second conductive layer is in contact with the first electrode;
the outer side surface of the first semiconductor layer comprises: at least one side surface that is located between the top surface and the bottom surface of the first semiconductor layer and exposed to the outside.

10. The light-emitting chip according to claim 9, wherein at least one of the first conductive layer and the second conductive layer is a reflective layer.

11. The light-emitting chip according to claim 10, wherein the second conductive layer is a reflective layer, and a surface of the second conductive layer is a rough surface.

12. The light-emitting chip according to claim 10, wherein the light-emitting chip further comprises at least one of the following:
a first insulating reflective layer, disposed on a surface, far away from the epitaxial layer of the light-emitting chip, of the first conductive layer;
a second insulating reflective layer, disposed on the bottom surfaces of the first semiconductor layer and the first active layer.

13. The light-emitting chip according to claim 6, wherein at least one of two side surfaces, in contact with the two substrates, of the connecting layer is a reflective rough surface.

14. The light-emitting chip according to claim 13, wherein the reflective rough surface is a serrated surface provided with serrated protrusions, and inclined surfaces of the serrated protrusions face the top surface of the substrate.

15. The light-emitting chip according to claim 1, wherein the epitaxial layer of the light-emitting chip is an epitaxial layer of an ultraviolet light chip.

16-18. (canceled)
